(19) United States
(12) Patent Application Publication
(10) Pub. No.: US 2019/0341265 A1
(43) Pub. Date: Nov. 7, 2019

(54) MASK AND FABRICATION METHOD THEREOF

(71) Applicant: Ningbo Semiconductor International Corporation, Ningbo (CN)

(72) Inventors: Mengbin LIU, Ningbo (CN); Hailong LUO, Ningbo (CN)

(21) Appl. No.: 16/206,617

(22) Filed: Nov. 30, 2018

Related U.S. Application Data
(63) Continuation of application No. PCT/CN2018/101764, filed on Aug. 22, 2018.

(30) Foreign Application Priority Data
May 3, 2018 (CN) 201810415650.0

(51) Int. Cl. H01L 21/308

(52) U.S. Cl. CPC H01L 21/3086; H01L 21/3081

(57) ABSTRACT

A mask and a fabrication method for the mask are provided. An exemplary mask includes a substrate, including a first surface, a second surface opposite to the first surface, and a plurality of openings passing through the substrate. A mask pattern layer is disposed on the first surface of the substrate and includes a pattern region and a shield region adjacent to the pattern region. The pattern region contains at least one through-hole passing through the mask pattern layer, and the pattern region is exposed by and corresponds to one opening of the plurality of openings. A protection layer is disposed on the shield region of the mask pattern layer facing away from the substrate. A first sacrificial layer is disposed between the mask pattern layer and the protection layer.

### CROSS-REFERENCE TO RELATED APPLICATIONS

This application is a continuation application of PCT Patent Application No. PCT/CN2018/101764, filed on Aug. 22, 2018, which claims the priority to Chinese Patent Application No. 201810415650.0, filed on May 3, 2018, the contents of all of which are incorporated herein by reference in their entirety.

### TECHNICAL FIELD

The present disclosure generally relates to the field of semiconductor manufacturing technology, and more particularly, relates to a mask and its fabrication method.

### BACKGROUND

Physical vapor deposition (PVD) technology mainly includes two processes: an evaporation process and a sputtering process. The evaporation process is used for forming a functional layer on a substrate surface. In this process, an evaporation source material, such as a plating metal, an alloy, or a compound, is heated in a vacuum evaporator and molten to escape to a molecular or atomic state in vapor phase, followed by a deposition on the substrate surface to form a solid thin film or coating.

Presently, the evaporation process mainly uses a metal mask. The metal mask has one or more through-holes in a pre-designed pattern. In the evaporation process, the metal mask is fixed between an evaporation source and the receiving surface of the substrate. The evaporation source material is deposited on the receiving surface through the through-hole to form a thin film with the pre-designed pattern.

A metal mask for manufacturing an organic light-emitting diode (OLED) is usually formed using an Invar alloy with a thickness of 30 μm to 50 μm by a chemical etching process. In the etching process, firstly, the Invar alloy surface is coated with a photoresist layer or photosensitive dry film. A fine pattern for the mask is transferred to the photoresist layer or photosensitive dry film by light exposure, followed by a development process and a chemical etching process to form a fine metal mask. Such processes often provide minimum feature sizes at micrometer level. Generally, the minimum feature sizes can only be reduced to be 25 μm to 40 μm. Thus, quality and precision of the metal mask may not meet semiconductor process requirements and demands.

### SUMMARY

One aspect of the present disclosure provides a mask. The mask includes a substrate, including a first surface, a second surface opposite to the first surface, and a plurality of openings passing through the substrate. A mask pattern layer is disposed on the first surface of the substrate and includes a pattern region and a shield region adjacent to the pattern region. The pattern region contains at least one through-hole passing through the mask pattern layer, and the pattern region is exposed by and corresponds to one opening of the plurality of openings. A protection layer is disposed on the shield region of the mask pattern layer facing away from the substrate. A first sacrificial layer is disposed between the mask pattern layer and the protection layer.

Another aspect of the present disclosure provides a fabrication method of the mask. In the method, a substrate is provided. The substrate includes a first surface and a second surface opposite to the first surface. A mask material layer is formed on the first surface of the substrate. A mask pattern layer is formed by: patterning the mask material layer to form a pattern region and a shield region adjacent to the pattern region. The pattern region includes at least one through-hole passing through the mask material layer. A first sacrificial layer is formed covering the mask pattern layer and filling in the at least one through-hole. A protection layer is formed on the first sacrificial layer corresponding to the shield region of the mask pattern layer. After forming the protection layer, the second surface of the substrate is etched to form a plurality of openings passing through the substrate, with each opening exposing the pattern region of the mask pattern layer. After forming the plurality of openings, a portion of the first sacrificial layer corresponding to the pattern region of the mask pattern layer is removed using the protection layer and the substrate as an etch mask.

Other aspects of the present disclosure can be understood by those skilled in the art in light of the description, the claims, and the drawings of the present disclosure.

### BRIEF DESCRIPTION OF THE DRAWINGS

The following drawings are merely for illustrative purposes according to various embodiments and are not intended to limit the scope of the present disclosure.

FIG. 1 illustrates a schematic structure of an exemplary mask according to various disclosed embodiments of the present disclosure;

FIG. 2 illustrates a schematic structure of another exemplary mask according to various disclosed embodiments of the present disclosure;

FIGS. 3 to 10 illustrate schematic structures corresponding to certain stages for fabricating an exemplary mask according to the first embodiment of the present disclosure;

FIGS. 11 to 15 illustrate schematic structures corresponding to certain stages for fabricating another exemplary mask according to the second embodiment of the present disclosure;

FIGS. 16 and 17 illustrate schematic structures corresponding to certain stages for fabricating another exemplary mask according to the third embodiment of the present disclosure; and

FIGS. 18 to 21 illustrate schematic structures corresponding to certain stages for fabricating another exemplary mask according to the fourth embodiment of the present disclosure.

### DETAILED DESCRIPTION

References will now be made in detail to exemplary embodiments of the disclosure, which are illustrated in the accompanying drawings. Wherever possible, the same reference numbers are used in the drawings of the same embodiment to refer to the same or alike parts.

Various embodiments provide masks and their fabrication methods. An exemplary mask (also referred to as “mask plate”) of the present disclosure may be fabricated using semiconductor manufacturing tools in semiconductor manufacturing processes, including, for example, deposition, photolithography, and/or etching processes. Compared to conventional chemical etching methods for fabricating metal masks, use of the semiconductor manufacturing tools for forming masks may improve mask quality and dimensional precision of the through-holes, for example. Additionally, the disclosed mask may have decreased minimum feature sizes for the through-holes and decreased thickness for mask pattern layer in order to meet continuous demands for decreasing the size of semiconductor structures and reducing dimensional limitations imposed by the evaporation technology.

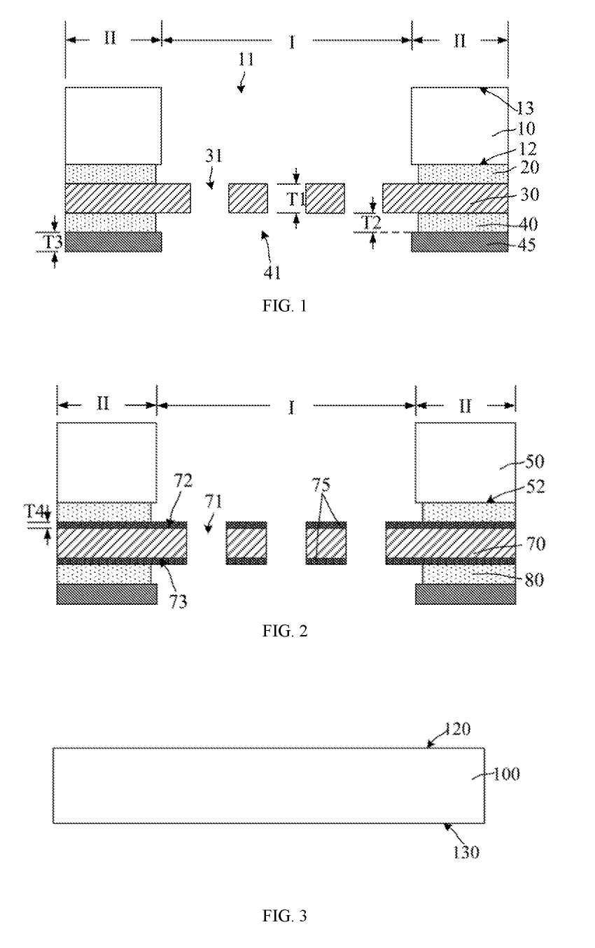

FIG. 1 illustrates a schematic structure of an exemplary mask according to various disclosed embodiments of the present disclosure.

As shown in FIG. 1, the mask includes a substrate 10. The substrate 10 has a first surface 12, a second surface 13 opposite to the first surface 12, and a plurality of first openings 11 through the substrate 10. The substrate 10 may be patterned by a semiconductor etching process. A mask pattern layer 30 is on the first surface 12 and the mask pattern layer 30 includes a pattern region I, an adjacent shield region II, and in the pattern region I at least one through-hole 31 passing through the mask pattern layer 30. The first openings 11 expose the pattern regions I, and each pattern region I corresponds to one of the first openings 11.

The mask may be used in an evaporation process, in which the evaporation source material travels first through the first openings 11 then through the through-hole 31 of the mask pattern layer 30 to reach a receiving surface. The mask may be fabricated by a semiconductor manufacturing process including, for example, deposition, photolithography, and/or etching processes. Compared to the conventional chemical etching method for fabricating metal masks, the semiconductor manufacturing processes used herein may improve mask quality and dimensional precision of the through-hole 31.

In addition, the mask pattern layer 30 may be formed on the substrate 10 using semiconductor manufacturing processes, which allow the substrate 10 to function as a support and fixture to the mask pattern layer 30. The conventional metal mask is often laser welded to a metal mask frame for use. During the welding process, uneven stress exerted to the metal mask or heat dissipation problems often occur, leading to a dislocation of the metal mask from the metal mask frame. In contrast, the disclosed mask by its fabrication method prevents dislocation of the mask pattern layer 30 from the substrate 10, thus improving the quality and precision of the mask pattern layer 30.

In an exemplary embodiment, by a semiconductor etching process, the substrate 10 may be patterned to form a plurality of the first openings 11.

The substrate 10 may be a semiconductor substrate, or any suitable substrate used in semiconductor manufacturing processes. For example, the substrate 10 may be a silicon substrate. In other embodiments, the material of the substrate 10 may be selected from germanium, silicon germanium, silicon carbide, gallium arsenide, or indium gallium, etc. The substrate may also be a silicon on insulator (SOI), a germanium on insulator (GOI), or any other suitable types of semiconductor substrates. The substrate material is chosen according to the semiconductor process requirements and chosen to be easily integrated.

In other embodiments, the substrate may be made of other materials suitable for a patterning process by a semiconductor etching process. For example, the substrate may be made of silicon oxide, or any other suitable material.

The first surface 12 of the substrate 10 may provide a process platform for forming the mask pattern layer 30, and the second surface 13 of the substrate 10 may provide a process platform for forming the first openings 11.

The substrate 10 may be a planar substrate to lower the process difficulties in forming the mask and to facilitate the actual use of the mask.

A plurality of first openings 11 may be formed. Each pattern region I is exposed by and corresponds to one of the first openings 11. During the evaporation process, evaporation source material passes through the first openings 11 and the through-holes 31 in the mask pattern layer to form a thin film with a pre-designed pattern. In FIG. 1, although only one first opening 11 and one corresponding pattern region I are shown for illustration purposes, one of ordinary skill in the art would know that any suitable number of first openings and pattern regions may be encompassed within the scope of the present disclosure.

In one embodiment, projection of the first opening 11 on the mask pattern layer 30 overlaps the pattern region I; correspondingly, the shield region II is covered by the substrate 10 and projection of the substrate 10 onto the mask pattern layer 30 overlaps the shield region II.

In an actual use of the mask, the surface of the mask pattern layer 30 facing away from the substrate 10 faces a receiving surface of the evaporation deposition. The opposite surface of the mask pattern layer 30 facing the substrate 10 in the pattern region I is open to the evaporation source. The deposition material from the evaporation source passes through the first opening 11 and the through-hole 31 sequentially to reach the receiving surface to form the pre-designed pattern. The shield region II of the substrate 10 acts to mask regions of the mask pattern layer not to receive the deposition material from the evaporation source, thereby forming the pre-designed pattern.

FIG. 1 shows three through-holes 31 in a pattern region I through the mask pattern layer 30 for the purpose of illustration. In other embodiments, the number of through-hole is not limited to three. In practice, the actual number of the through-hole will be determined by process requirements.

The material for the mask pattern layer 30 is chosen to be a commonly used material with high semiconductor process integrability, for the purpose of reducing difficulty of the mask fabrication process.

In one embodiment, the mask pattern layer 30 may be made of silicon nitride. The silicon nitride material is a hard material, providing desirable mechanical strength for the mask pattern layer 30, and reducing the probability of the mask pattern layer 30 to fracture or to bending deformation, therefore increasing mask quality and dimensional precision of the through-hole 31.

In other embodiments, the mask pattern may be made of a material including, silicon oxide, silicon oxynitride, silicon carbon nitride, polycrystalline silicon, aluminum, or a combination thereof.

Furthermore, an increase of the depth T1 of the through-hole 31 would increase the thickness of the mask pattern layer 30, thereby increasing the mechanical strength of the mask. Thus, the depth T1 should be sufficiently large for mechanical properties of the mask pattern layer 30, for high quality and proper function of the mask, but not so high as to make the mask pattern layer 30 too thick, to cause undesirable shadow effects during the evaporation process, thus negative side effects on morphology of the deposited thin film. In one embodiment, the depth T1 is approximately 2 μm to 10 μm and thickness of the mask pattern layer 30 is approximately 2 μm to 10 μm.

Compared to the conventional metal masks, the mask of the present disclosure is fabricated by semiconductor manufacturing processes, which allows further decreasing of the dimensions of the through-hole 31 and meeting continuous demands of reducing feature sizes (or critical dimensions) of the semiconductor structures.

In one embodiment, the through-hole 31 is in a circular shape. In other embodiments, the through-hole 31 may take any other shapes based on actual requirements for morphology of the deposited thin film.

Still referring to FIG. 1, the mask may include a protection layer 45 on the surface of the shield region II of the mask pattern layer 30 facing away from the substrate 10, and a first sacrificial layer 40 between the mask pattern layer 30 and the protection layer 45. For the mask to function properly, a second opening 41 may be formed through the first sacrificial layer 40 and the protection layer 45 to expose the pattern region I of the mask pattern layer 30.

The disclosed mask is fabricated by semiconductor manufacturing processes including, for example, deposition, photolithography, and/or etching processes. Before forming the first openings 11 by the semiconductor etching process, the mask pattern layer 30 may be covered by the first sacrificial layer 40, which offers a support for the mask pattern layer 30 during the etching process to produce the first openings 11. Such support reduces the probability of separation or fracture of the mask pattern layer 30, further increasing quality and precision of the mask.

Also, when forming the protection layer 45 by an etching process, the sacrificial layer 40 may prevent polymer by-products formed during the etching process from being attached to the sidewalls of the through-hole 31, thus avoiding an etching loss of the substrate 10 via the through-hole 31 during the etching process.

For the mask to function properly, after forming the first openings 11, the mask fabrication may further include removal of a portion of the first sacrificial layer 40 in the pattern region I, so as to form the second openings 41 through the first sacrificial layer 40 and the protection layer 45 to expose the pattern region I in the mask pattern layer 30. The first opening 11, the through-hole 31, and the second openings 41 are therefore connected through from one to another.

The materials for the first sacrificial layer 40, for the mask pattern layer 30, and for the substrate 10 are chosen with high etch rate selectivity. The materials of the first sacrificial layer 40 are easily removable so as to lower the process difficulties in etching and to decrease the damage caused to the mask pattern layer 30 and substrate 10 by the etching process of the sacrificial layer 40.

In one embodiment, the material of the first sacrificial layer 40 is different from the material for the mask pattern layer 30. For example, the first sacrificial layer 40 is made of silicon oxide. In other embodiments, the material of the first sacrificial layer may be selected from silicon nitride, amorphous carbon, or germanium.

Furthermore, an increase of the thickness T2 of the first sacrificial layer 40 would increase mechanical strength of the first sacrificial layer 40. Thus, the thickness T2 should be sufficiently large for the first sacrificial layer 40 to support the mask pattern layer 30. But if too large, the distance between the surface of the mask pattern layer 30 facing the sacrificial layer 40 and the surface to receive the evaporation deposition would be so great as to increase undesirable shadow effects during the evaporation process, thereby producing negative effects on morphology of the deposited thin film. In one embodiment, the thickness T2 is approximately 2 μm to 10 μm.

In one embodiment, when removing the first sacrificial layer 40, the protection layer 45 performs the following functions as an etching mask: to protect the shield region II of the first sacrificial layer 40; to prevent excessive removal or complete removal of the first sacrificial layer 40 in the shield region II; to allow the remaining sacrificial layer 40 to function as a support for the mask pattern layer 30; and to further decrease the probability of separation of mask pattern layer 30 from the substrate 10 or of fracture of the mask pattern layer 30.

Thus, the etch rate selectivity between the materials for the first sacrificial layer 40 and the protection layer 45 is to be substantially high. For the purpose of decreasing difficulty of the mask fabrication process, the material for the protection layer 45 is chosen to be commonly used, and to have good masking effect with high process integrability.

In one embodiment, the protection layer 45 is made of polycrystalline silicon material. In other embodiments, the material of the protection layer 45 may include silicon nitride, silicon oxide, silicon oxynitride, silicon carbon nitride, or aluminum.

Furthermore, the thickness T3 of the protection layer 45 should be sufficiently large for providing protection to the first sacrificial layer 40, but not so large as to make the distance between the surface of the mask pattern layer 30 facing the first sacrificial layer 40 and the evaporation receiving surface too great, which would increase undesirable shadow effects during the evaporation process and negatively affect morphology of the deposited thin film. In one embodiment, the thickness T3 is approximately 2 μm to 10 μm, and the thickness of the mask pattern layer 30 is approximately 2 μm to 10 μm.

In one embodiment, the mask may further include: a second sacrificial layer 20, placed between the substrate 10 and the mask pattern layer 30.

The second sacrificial layer 20 covers the first surface 12 of the substrate 10 before forming the first opening 11. First openings 11 are formed by an etching process to the substrate 10. The second sacrificial layer 20 provides protection for the mask pattern layer 30 during the etching process, thereby reducing probability of damage to the mask pattern layer 30 by the etching process, and further increasing quality of the mask.

To expose the through-hole 31 through the first openings 11, the mask fabrication process may include, for example, removing a portion of the second sacrificial layer 20 exposed by the first openings 11, making the first openings 11 and the through-hole 31 connected through from one to the other, and thus enabling the mask to function properly.

The materials for the second sacrificial layer 20, mask pattern layer 30, and substrate 10 are selected to have substantially high etch rate selectivity. The material of the second sacrificial layer 20 is easily removable so as to lower process difficulties in removing the second sacrificial layer 20 and to decrease the damage loss to the substrate 10 and the mask pattern layer 30 caused by the etching process to remove the second sacrificial layer.

In one embodiment, the material of the second sacrificial layer 20 is different from the material of the mask pattern layer 30. The same material may be selected for the second sacrificial layer 20 and the first sacrificial layer 40 so that the sacrificial layers 20 and 40 are removed simultaneously in one process to simplify the process, resulting in an increased process efficiency.

For example, the first sacrificial layer 40 may be made of silicon oxide. The second sacrificial layer 20 may also be made of silicon oxide. In other embodiments, the second sacrificial layer may be made of a material including silicon nitride, amorphous carbon, or germanium.

FIG. 2 illustrates a schematic structure of another exemplary mask according to various disclosed embodiments of the present disclosure. Certain similarities between this embodiment and the previous embodiment are not repeated here. One of the differences differentiating this embodiment from the previous one is that the mask may further include a metal layer 75 for the purpose of increasing mechanical strength of the mask pattern layer 70.

The mask pattern layer 70 includes a third surface 72 facing the first surface 52 of the substrate 50, and a fourth surface 73 opposite to the third surface layer 72. The metal layer 75 may cover the third surface 72 and the fourth surface 73, or cover the fourth surface 73 and sidewalls of the through-hole 71, or cover only the third surface 72.

The metal layer 75 may provide a support for the mask pattern layer 70, thereby decreasing the probability of fracture or bending deformation of the mask pattern layer 70 and increasing mechanical strength of the mask pattern layer 70. Such support would further increase mechanical strength and quality of the mask and dimensional precision of the through-hole 71.

The mask is routinely cleaned after completion of the evaporation process. The metal layer 75 protects the mask pattern layer 70 during the cleaning process, preventing corrosion of the mask layer 70 from the cleaning solution, thereby increasing service life of the mask.

The metal layer 75 has high mechanical strength and corrosion resistance. Particularly, the material of the metal layer 75 may be selected from Ni, Ag, Au, Cu, Pt, Cr, Mo, Ti, Ta, Sn, W, Al, or a combination thereof.

In one embodiment, the metal layer 75 covers the third surface 72 and the fourth surface 73, which are the two opposite surfaces of the mask pattern layer 70. Thus, the metal layer 75 may increase the mechanical strength of the mask pattern layer 70 significantly while avoiding the problem of the metal layer 75 occupying too much space in the through-hole 71, thereby decreasing a negative influence on the evaporation process and on the quality of the deposited film.

In one embodiment, the through-hole 71 is in a circular shape. In other embodiments, the through-hole 71 may take other shapes based on actual requirements for the morphology of the deposited film.

Furthermore, an increase of the thickness T4 of the metal layer 75 would increase protection of the mask pattern layer 70 from fracture or bending deformation. Thus, the thickness T4 of the metal layer 75 should be sufficiently large for increasing mechanical strength of the mask and protection of the mask pattern layer 70, but not so large as to make overall thickness of the mask too great, increasing undesirable shadow effects during the evaporation process, or for the metal layer 75 to occupy too much space in the openings of the through-hole 71, and thereby affect proper function of the mask. In one embodiment, the thickness T4 of the metal layer 75 is less than the radius of the through-hole 71 (not shown in the FIG. 2). When the metal layer 75 covers the fourth surface layer 73 and sidewall of the through-hole 71, the thickness of the metal layer 75 on the sidewalls of the through-hole 71 is less than the through-hole radius.

The metal layer 75 has high mechanical strength. Even a relatively thin metal layer 75 would further enhance mechanical strength of the mask. Thus, on assurance of mask quality and dimensional precision of the through-hole 71, the thickness of either the mask pattern layer 70 (not shown) or the first sacrificial layer 80 (not shown) may be suitably reduced in order to decrease overall thickness of the mask and to minimize undesirable shadow effects during the deposition process.

FIGS. 3 to 10 illustrate schematic structures corresponding to certain stages for fabricating an exemplary mask according to the first embodiment of the present disclosure;

Referring to FIG. 3, a substrate 100 includes a first surface 120, and a second surface 130 opposite to the first surface 120.

The substrate 100 provides a support and fixture for the mask pattern layer of the mask.

In the first embodiment, the substrate 100 may be patterned by a semiconductor etching process, so that the first openings may be formed in the substrate 100 by a etching process in one of the subsequent processes.

The substrate 100 may be made of a semiconductor substrate, which is commonly used in the semiconductor manufacturing processes.

The substrate 100 is made of silicon material in the first embodiment. In other embodiments, the material of the substrate 100 may be selected from germanium, silicon germanium, silicon carbide, gallium arsenide, indium gallium, etc. The substrate may also be selected from a silicon on insulator (SOI) or germanium on insulator (GOI) as well as other types of semiconductor substrates. The substrate material may be chosen according to semiconductor process requirements and chosen to be easily integrated.

In other embodiments, other materials suitable for the semiconductor etching process to produce patterns may be used for the substrate, for example, silicon oxide substrate, etc.

The first surface 120 may provide a process platform for a subsequent fabrication process of the mask pattern layer, and the second surface 130 may provide a process platform for a subsequent process of forming the first openings in the substrate 100. For decreasing difficulty of the mask fabrication process and benefiting practical use of the mask, the substrate 100 is a planar substrate.

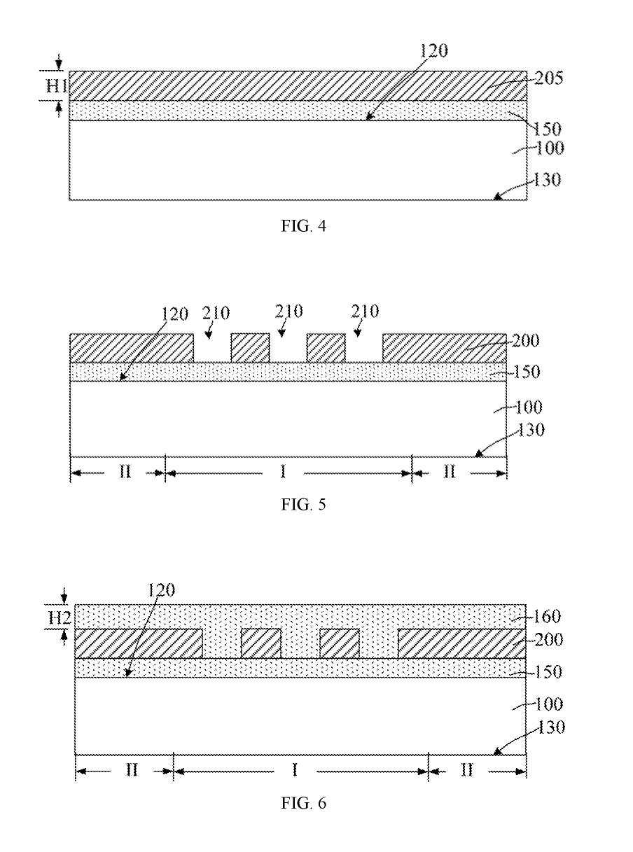

Referring to FIG. 4, a mask material layer 205 is formed on the first surface 120. The mask material layer 205 provides a process base for subsequent fabrication processes to produce a mask pattern layer with through-holes. In other words, the mask material layer 205 undergoes a patterning process to form the mask pattern layer.

For decreasing process difficulties of the mask fabrication, the material for the mask material layer 205 is chosen from commonly used materials with high process integrability.

In the first embodiment, the mask material layer 205 is made of silicon nitride. The silicon nitride material is hard, providing an increased mechanical strength for the later formed mask pattern layer, reducing the probability of bending deformation and fracture of the mask pattern layer, therefore increasing mask quality and dimensional precision of the through-hole.

In other embodiments, the mask material layer may be made of silicon oxide, silicon oxynitride, silicon carbon nitride, polycrystalline silicon, or aluminum.

Furthermore, an increase of the thickness H1 of the mask material layer 205 would increase mechanical strength of the mask pattern layer, thereby increasing mechanical strength of the mask. Thus, the thickness H1 of the mask material layer 205 should be sufficiently large for mechanical strength of the mask pattern layer, quality of the final mask, and precision of the through-hole, but not so large as to make depth of the through-hole too high, to cause undesirable shadow effects during the evaporation process, and to negatively affect morphology of the deposited thin film. In the first embodiment, the depth H1 is approximately 2 μm to 10 μm (shown in FIG. 4); the thickness of the mask pattern layer 200 (not shown) is approximately 2 μm to 10 μm; and the depth of the through-hole 210 (not shown) is approximately 2 μm to 10 μm.

Referring to FIG. 5, the mask material layer 205 (shown in FIG. 4) is patterned to form the pattern region I, and adjacent shield region II. At least one through-hole 210 is formed in the pattern region I passing through the mask material layer 205. The remaining mask material layer 205 becomes the mask pattern layer 200 after the patterning process.

A thin film with a pre-designed pattern may be formed through the mask pattern layer 200 during the evaporation process.

In an actual process of using the mask, the surface of the mask pattern layer 200 facing away from the substrate 100 faces the receiving surface of the evaporation deposition. The surface of the mask pattern layer 200 facing the substrate 100 faces the evaporation source. The deposition material from the evaporating source passes through the through-hole 210 to reach the receiving surface and to form the thin film with the pre-designed pattern.

In the first embodiment, three through-holes 210 in the pattern region I within the mask pattern layer 200 are illustrated for the purpose of demonstration. In other embodiments, the number of the through-hole 210 is not limited to three but is determined by the requirements of actual process.

In the first embodiment, the through-hole 210 is in a circular shape. In other embodiments, the through-hole 210 may take other shapes based on morphology requirements of the thin film.

In the first embodiment, the mask material layer 205, thus the mask pattern layer 200, is made of silicon nitride material. In other embodiments, the mask pattern layer may be made of silicon oxide, silicon oxynitride, silicon carbon nitride, polycrystalline silicon, or aluminum.

In the first embodiment, the thickness of the mask material layer, H1 (shown in FIG. 4) is approximately 2 μm to 10 μm. Correspondingly, the thickness of the mask pattern layer (not shown in FIG.) is approximately 2 μm to 10 μm, and the depth of the through-hole (not shown in FIG.) is approximately 2 μm to 10 μm.

Compared to the conventional metal masks (for example, a fine metal mask), the mask in the first embodiment is fabricated by semiconductor manufacturing processes, which provide advantages of allowing further decreasing of the opening sizes of the through-hole 210 and meeting continuous demands to minimize feature sizes of the semiconductor structures.

The fabrication process of the mask pattern layer 200 may include: forming a first photoresist layer (not shown in FIG.) on the mask material layer 205; the photoresist layer has first pattern openings exposing a portion of the pattern region I in the mask material layer 205 (not shown in FIG.); etching the mask material layer 205 along the first pattern openings; forming the through-hole 210 in the pattern region I passing through the mask material layer 205; the remaining mask material layer 205 becoming the mask pattern layer 200; and removing the first photoresist layer.

In the first embodiment, the etching of the mask material layer 205 is conducted by a dry etching method to enhance quality of the through-hole 210 in terms of morphology.

Referring to FIG. 6, a first sacrificial layer 160 is formed to cover the mask pattern layer 200 and to fill the through-hole 210 (shown in FIG. 5).

The first sacrificial layer 160 provides a support for the mask pattern layer 200 during a subsequent etching process that forms the first openings in the substrate 100, thereby reducing the probability of separation, bending deformation, or fracture of the mask pattern layer 200, and further increasing the quality of the mask.

A protection layer may be formed on the first sacrificial layer 160 through subsequent deposition and etching processes, during which the first sacrificial layer 160 may prevent the polymer by-products from being attached to the sidewalls of the through-hole 210, and may avoid etching damage to the substrate 100 via the through-hole 210.

A subsequent process includes removing a portion of the first sacrificial layer 160 in the pattern region I to form the second openings that pass through the first sacrificial layer 160. The first openings, the through-hole 210, and the second openings are connected through from one to another to enable proper function of the mask. The materials for the first sacrificial layer 160, for the mask pattern layer 200, and for the substrate 100 are chosen to have high etch rate selectivity. The material of the first sacrificial layer 160 is easily removable in order to decrease process difficulties in removing the first sacrificial layer 160 and to minimize possible damage to the substrate 100 and to the mask pattern layer 200 during the process of removing the first sacrificial layer 160.

In the first embodiment, the material of the first sacrificial layer 160 is different from the material of the mask pattern layer 200. For example, the first sacrificial layer is made of silicon oxide, which is different from the material used for the mask pattern layer 200. The process of removing silicon oxide material is simple and the cost of silicon oxide is low. These advantages offer a low fabrication cost of the mask.

In other embodiments, the first sacrificial layer 160 may be made of silicon nitride, amorphous carbon, or germanium.

Furthermore, an increase of the thickness H2 of the first sacrificial layer 160 on the mask pattern layer 200 would increase support for the mask pattern layer 200. Thus, the thickness H2 should be sufficiently large to support the mask pattern layer 200, to provide for the protection of the substrate 100, and to enhance the mechanical properties of the mask, but not so large as to make the distance between the surface of the mask pattern layer 200 facing the first sacrificial layer 160 and the evaporation receiving surface so great as to increase the shadow effect during the evaporation process and to cause a negative effect on morphology of the deposited film. In the first embodiment, the thickness H2 is approximately 2 μm to 10 μm.

Referring again to FIG. 4, before forming the mask material layer 205, a second sacrificial layer 150 is formed on the first surface 120 of the substrate 100. Sequentially, a mask material layer 205 is formed on the second sacrificial layer 150.

The second sacrificial layer 150 protects the mask pattern layer 200 in the subsequent etching process for the substrate 100, decreasing the probability of damaging the mask pattern layer 200, thereby increasing quality of the mask.

For the mask to function properly, the first openings in the substrate 100 and the through-hole 210 in the mask pattern layer 200 must connect through from one to the other (referring to FIG. 5), so a portion of the second sacrificial layer 150 exposed through the first openings is removed in a subsequent process. The materials for the second sacrificial layer 150, the mask pattern layer 200, and the substrate 100 are chosen to have relatively high etch rate selectivity. The material of the second sacrificial layer 150 is easily removable in order to reduce difficulty of the process for removing the second sacrificial layer 150 through the first openings and to minimize damage to the substrate 100 and the mask pattern layer 200 during the process.

In the first embodiment, the materials for the second sacrificial layer 150 and for the mask pattern layer 200 are different (shown in FIG. 6). The same material may be used for the first 160 sacrificial layer and the second 150 sacrificial layer for the purpose of removing both sacrificial layers simultaneously in one process, simplifying the process, therefore, increasing the process efficiency.

In the first embodiment, the first sacrificial layer 160 is made of silicon oxide material. The same material is used for the second sacrificial layer 150. In other embodiments, the material for the second sacrificial layer may be selected from silicon nitride, amorphous carbon, or germanium.

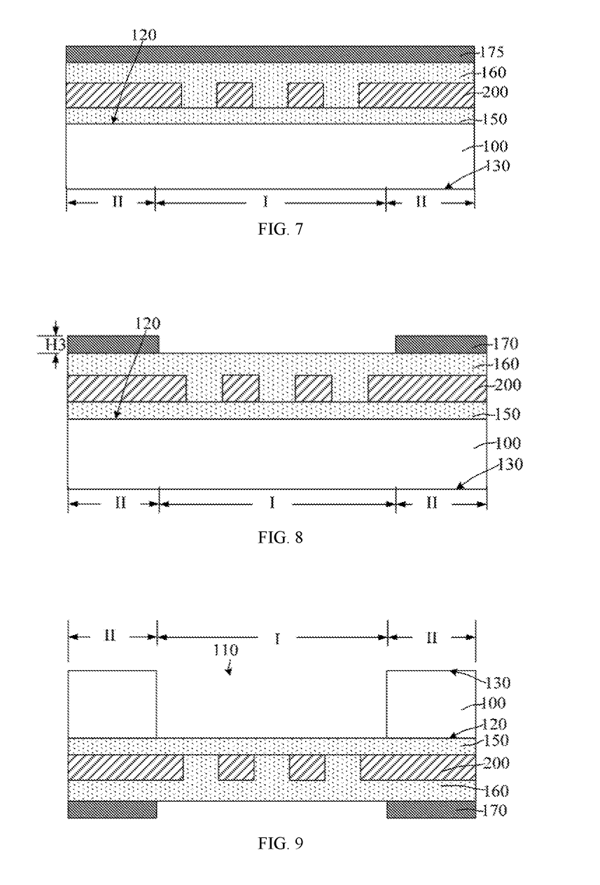

Referring to FIGS. 7 and 8, a protection layer 170 may be formed in the shield region II on the first sacrificial layer 160 (shown in FIG. 8).

In a subsequent etching process for the first sacrificial layer 160, the protection layer 170 functions as a mask to protect the first sacrificial layer 160 in the shield region II from excessive or complete removal, assisting the remaining sacrificial layer after etching in the role of supporting the mask pattern layer 200, and minimizing the probabilities of the mask pattern layer separating from the substrate 100, bending deformation, or fracturing.

The materials for the protection layer 170 and for the first sacrificial layer 160 are chosen to have high etch rate selectivity. The material of the protection layer 170 may be selected from commonly used materials with high process integrability for the purpose of reducing difficulty of the mask fabrication. In the first embodiment, the protection layer 170 is made of polycrystalline silicon. In other embodiments, the protection layer 170 may be made of silicon nitride, silicon oxide, silicon oxynitride, silicon carbon nitride, or aluminum.

The thickness H3 of the protection layer 170 should be sufficiently large for the protection of the first sacrificial layer 160, but not so large as to increase the distance between the surface of the mask pattern layer facing the first sacrificial layer 160 and the evaporation receiving surface so much as to increase the shadow effect during the evaporation process and to cause a negative effect on morphology of the deposited film. In the embodiment, the thickness H3 is approximately 2 μm to 10 μm.

The process for forming the protection layer 170 may include: forming a protection film 175 on the first sacrificial layer 160 (shown in FIG. 7); and patterning the protection film 175 to expose the first sacrificial layer 160 in the pattern region I; so that the remaining protection film 175 becomes the protection layer 170 after the patterning.

In the first embodiment, the protection film 175 may be patterned by the dry etching method to increase profile quality of the protection layer 170.

Referring to FIG. 9, after formation of the protection layer 170, the second surface 130 of the substrate 100 is etched to form a plurality of first openings 110 passing through the substrate 100 and exposing the pattern region I. Each of the plurality of first openings 110 corresponds to a pattern region I.

The substrate 100 provides a support and fixture for the mask pattern layer 200. The first openings 110 and the through-hole 210 are connected through from one to the other in a subsequent process, allowing the mask to function properly (shown in FIG. 5).

A plurality of the first openings 110 exposes the pattern region I. Each pattern region I corresponds to one of the first openings 110. During actual use of the mask, the deposition material from the evaporation source passes through the first openings 110 and the through-hole 210 sequentially to reach the receiving surface to form a thin film with the pre-designed pattern. In the first embodiment, only one first opening and one corresponding pattern region I are shown for illustration. One of ordinary skill in the art would know that any suitable number of first openings and pattern regions may be encompassed within the scope of the present disclosure.

In the first embodiment, projections of the first openings 110 on the mask pattern layer 200 overlap the pattern region I; the projection of the substrate 100 on the mask pattern layer 200 overlaps the shield region II. Accordingly, the etching process of the second surface 130 of the substrate 100 in the pattern region I is conducted.

A second sacrificial layer 150 may be formed on the first surface 120 of the substrate 100. Accordingly, the second sacrificial layer 150 may be exposed through the first openings 110 after formation of the first openings.

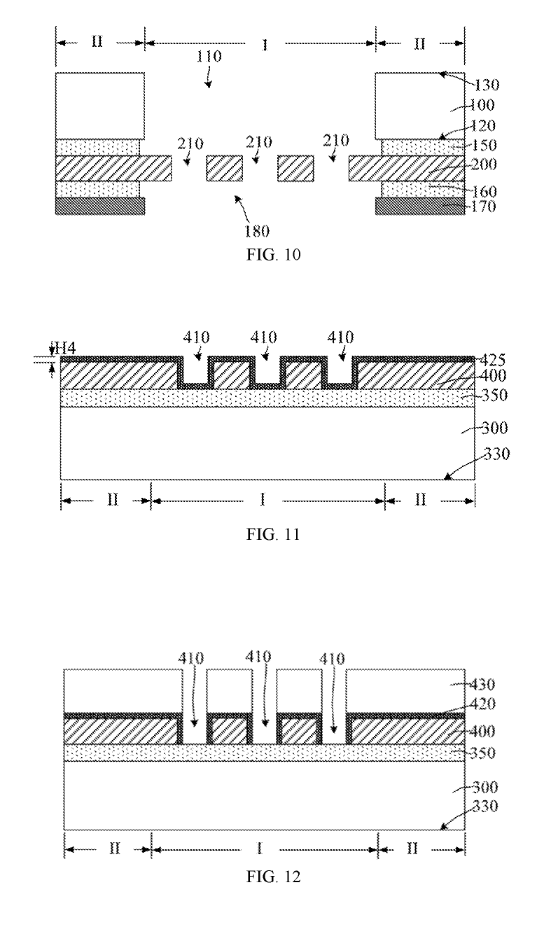

Referring to FIG. 10, after formation of the first openings 110, a portion of the first sacrificial layer 160 in the pattern region I is removed using the protection layer 170 and the substrate 100 as masks.

The removal of the first sacrificial layer 160 in the pattern region I forms second openings 180 passing through the protection layer 170 and the first sacrificial layer 160. Thus, the first openings 110, the through-hole 210, and the second openings 180 are connected through from one to another to enable the mask to function properly.

In the first embodiment, the removal of a portion of the first sacrificial layer 160 in the first openings 110 is by a wet etching process. The first sacrificial layer 160 may be made of silicon oxide; the etching solution for the wet etching process may be hydrofluoric acid. In other embodiments, for example, when the first sacrificial layer is amorphous carbon, an ashing process may be used to remove the first sacrificial layer exposed by the first openings.

As shown in FIG. 9, after formation of the first openings 110, the second sacrificial layer 150 is exposed through the first openings 110. As shown in FIG. 10, to make the first openings 110, the through-hole 210, and the second openings 180 connect through from one to another, a portion of the second sacrificial layer 150 in the pattern region I is removed using the protection layer 170 and the substrate 100 as masks.

In the first embodiment, the materials for both the first and the second sacrificial layers are silicon oxide in order to conduct the wet etching process simultaneously in the same removal process.

In other embodiments, when the materials for both the first and the second sacrificial layers 160 and 150 are amorphous carbon, the removal process for both the sacrificial layers may be carried out simultaneously in one step applying an ashing process. When the materials for the first sacrificial layer 160 and the second sacrificial layer 150 are different, different etching processes are applied to remove the first and the second sacrificial layers.

In the first embodiment, the mask is fabricated using semiconductor manufacturing processes including, for example, deposition, photolithography, and/or etching. Compared to the conventional chemical etching process to fabricate metal masks, the semiconductor manufacturing processes may increase the quality and dimensional precision of the through-hole 210, allowing further decrease of the opening size of the through-hole 210 and thickness of the mask pattern layer 200, meeting continuous demands of minimizing feature sizes of the semiconductor structures, and reducing dimension limitation imposed by the evaporation process on the opening size of the through-hole 210 and thickness of the mask pattern layer 200.

The mask pattern layer 200 is formed on the substrate 100 by using the semiconductor manufacturing processes. During the processes, the substrate 100 provides a support and fixture for the mask pattern layer 200. In contrast with the laser welding process to weld a metal mask to a metal frame, the semiconductor manufacturing processes prevent dislocation of the mask pattern layer 200 from the substrate 100, thus increasing the quality and precision of the mask, and precision of the evaporation process.

FIGS. 11 to 15 illustrate schematic structures corresponding to certain stages for fabricating another exemplary mask according to the second embodiment of the present disclosure. Some similarities between this embodiment and the first embodiment are not repeated here.

One of the differences is that in the second embodiment a metal layer 420 is formed on the surface of the mask pattern layer 400 facing away from the substrate 300 and on the sidewall of the through-hole 410.

The metal layer 420 may provide a support to the mask pattern layer 400, reducing the probability of fracture or bending deformation of the mask pattern layer 400, increasing the mechanical strength of the mask pattern layer 400 and the final mask, thereby improving quality of the mask and the precision of the through-hole 410 (referring to FIG. 15).

At completion of the evaporation process, the mask is routinely cleaned. The metal layer 420 may provide protection for the mask pattern layer 400 during the cleaning by preventing corrosion of the mask pattern layer 400 from the cleaning solution, thereby increasing service life of the mask.

The mask fabrication may include a process of forming a metal film 425 on the mask pattern layer 400 and on both sidewall and bottom of the through-hole 410 after formation of the mask pattern layer 400, as shown in FIG. 11.

The metal film 425 provides a process basis for a subsequent process of forming the metal layer. In other words, the metal film 425 is patterned to form the metal layer in a subsequent process.

The metal film 425 has high mechanical strength and corrosion resistance to provide for the mask pattern layer 400 an effective support and protection during the mask cleaning process. In the second embodiment, the material of the metal film is selected from Ni, Ag, Au, Pt, Cr, Mo, Ti, Ta, Sn, W, Al, or a combination thereof. The metal film 425 may be formed by a process of evaporation, sputtering, or plating.

Furthermore, an increase of the thickness H4 of the metal film 425 would increase the mechanical strength of the later formed metal layer, thereby further increasing the mechanical strength of the mask pattern layer 400. Thus, the thickness H4 should be sufficiently large to suppress the probability of fracture or bending deformation of the mask pattern layer 400, but not so large as to make overall thickness of the mask too great for the mask to function properly, to increase undesirable shadow effects during the evaporation process, or to reduce the quality of the metal film 425 on the sidewall of the through-hole 410. In the second embodiment, the thickness H4 is less than the radius of the through-hole 410 (not shown in FIG.).

More detailed description of the fabrication process of the mask pattern layer 400 as well as the processes before forming the mask pattern layer 400 may be referenced in the description of the first embodiment.

Referring to FIG. 12, a portion of the metal film 425 on the bottoms of the through-holes 410 is etched off to leave the remaining metal film 425 as the metal layer 420 (shown in FIG. 11).

In the second embodiment, the material for the metal film 425, which becomes the metal layer 420, may be selected from Ni, Ag, Au, Cu, Pt, Cr, Mo, Ti, Ta, Sn, W, Al, or a combination thereof.

The thickness of the metal layer 420 is less than the radius of the through-hole 410 (not shown). Accordingly, the thickness of the metal layer 420 on the sidewall of the through-hole 410 is less than the radius of the through-hole 410.

The process for forming the metal layer 420 may include: forming a second photoresist layer 430 on the metal film 425, where the second photoresist layer 430 covers the metal film 425 on the mask pattern layer 400 and on sidewall of the through-hole 410; leaving the metal film 425 in the bottom of the through-hole exposed; etching off a portion of the metal film 425 from the bottom of the through-hole 410 using the second photoresist 430 as a mask, preserving the metal film 425 on the mask pattern layer 400 and on the sidewall of the through-hole 410 to function as the metal layer 420; and removing the photoresist 430 after the formation of the metal layer 420.

In the second embodiment, after etching off a portion of the metal film 425 from the bottom of the through-hole 410, the metal layer 420 covers the surface of the mask pattern layer 400 facing away from the substrate 300 and the sidewall of the through-hole 410. The metal layer 420 provides a support for the mask pattern layer 400 and further increases its mechanical strength.

The metal layer 420 has high mechanical strength. Even a relatively thin metal layer 420 would further increase the mechanical strength of the mask. On assurance of mask quality and dimensional precision of the through-hole 410, the thickness of the mask pattern layer 400 may be suitably reduced to further decrease overall thickness of the mask and to improve the shadow effect during the evaporation process.

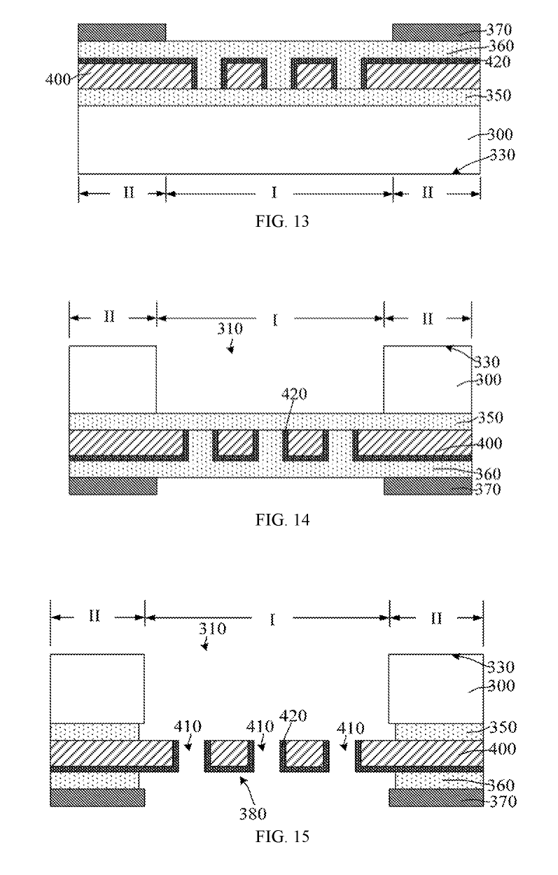

Referring to FIG. 13, after formation of the metal layer 420, a first sacrificial layer 360 may be formed to cover the metal layer 420 and to fill in the through-holes 410 (shown in FIG. 12), followed by forming a protection layer 370 in the shield region II on the first sacrificial layer 360. Referring to FIG. 14, after formation of the protection layer 370, the second surface 330 of the substrate 300 is etched to form a plurality of first openings 310 passing through the substrate 300 to expose the pattern region I. Each of the openings 310 corresponds to a pattern region I. Referring to FIG. 15, after formation of the first openings 310, a portion of the first sacrificial layer 360 and a portion of the second sacrificial layer 350 in the pattern region I are removed using the protection layer 370 and the substrate 300 as masks to form the second openings 380 passing through the protection layer 370 and the first sacrificial layer 360.

A more detailed description of the processes for forming the first sacrificial layer 360, the protection layer 370, the first openings 310, and the second openings 380 may be referenced to the description of the above described embodiment, which is not repeated here.

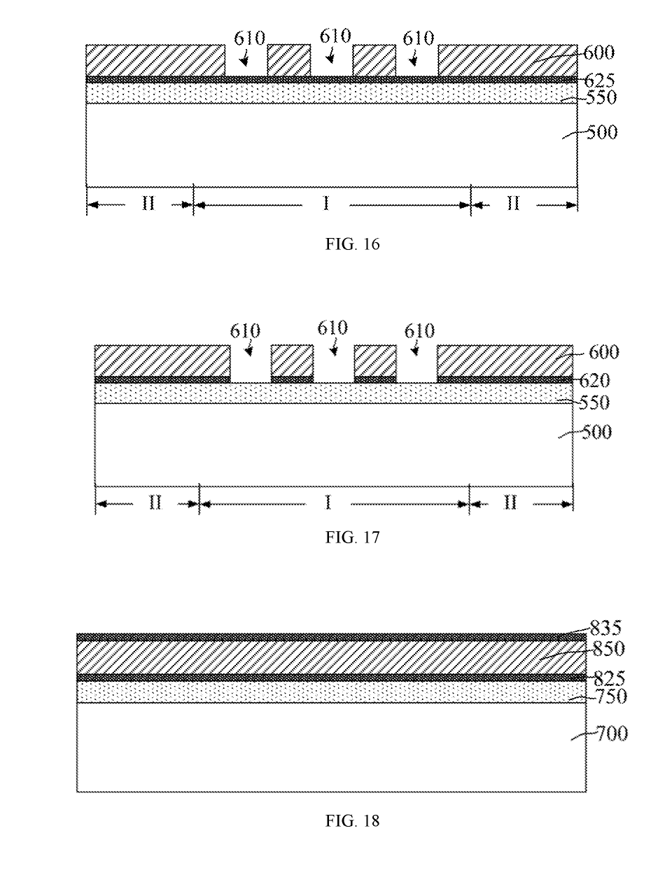

FIGS. 16 and 17 illustrate schematic structures corresponding to certain stages for fabricating an exemplary mask according to the third embodiment of the present disclosure. Some similarities between this embodiment and the second embodiment are not repeated here. One of the differences from the second embodiment is that the metal layer 620 covers only the surface of the mask pattern layer 600 facing the substrate 500, as shown in FIG. 17.

Referring to FIG. 16, a metal film 625 is formed on the first surface of the substrate 500 before forming the mask material layer (the first surface is not shown).

In the third embodiment, a second sacrificial layer 550 is formed on the first surface of the substrate 500 followed by forming a metal film 625 on the second sacrificial layer 550.

The material of the metal film 625 is selected from Ni, Ag, Au, Cu, Pt, Cr, Mo, Ti, Ta, Sn, W, Al, or a combination thereof. The metal film 625 may be formed by a process of an evaporation process, sputtering, or plating.

Referring again to FIG. 16, after formation of the metal film 625, the mask material layer is patterned to form the pattern region I and the adjacent shield region II. At least one through-hole 610 is formed in the pattern region I passing through the mask material layer. The remaining mask material layer becomes the mask pattern layer 600 after the patterning.

Referring to FIG. 17, after formation of the mask pattern layer 600, a portion of the metal film 625 is etched off from the bottoms of the through-holes 610 (shown in FIG. 16). The remaining metal film 625 becomes the metal layer 620. This etching process allows later formed first openings in the substrate 500 and the through-hole 610 to connect through from one to the other, thereby enabling the mask to function properly.

The metal film 620 covers the surface of the mask pattern layer 600 that faces the substrate 500, thereby increasing mechanical strength of the mask pattern layer 600 while avoiding the problem of the metal layer 620 occupying too much space in the through-hole 610, and decreasing negative effects on the evaporation process and on quality of the deposited thin film.

A more detailed description of the fabrication process is referenced in the descriptions of the first and the second embodiments, which are not repeated here.

FIGS. 18 to 21 illustrate schematic structures corresponding to certain stages for fabricating another exemplary mask according to the fourth embodiment of the present disclosure.

Some similarities between this embodiment and the second embodiment are not repeated here. One of the differences from the second embodiment is that the metal layer 820 covers the surface of the mask pattern layer 800 facing the substrate 700 and the surface facing away from the substrate 700, as shown in FIG. 21.

Coverage of the two opposite surfaces of the mask pattern layer 800 by the metal layer 820 increases mechanical strength of the mask pattern layer 800 substantially, and avoids the problem of the metal layer 820 occupying too much space in the through-hole 810, thereby decreasing the negative effect on the evaporation process and on quality of the film.

Referring to FIG. 18, a first metal film 825 is formed on the first surface (not shown) of the substrate 700, a mask material layer 850 is formed on the first metal film 825, and a second metal film 835 is formed on the mask material layer 850.

In the fourth embodiment, a second sacrificial layer 750 may be formed on the first surface of the substrate 700. Accordingly, a first metal film 825 is formed on the second sacrificial layer 750.

The material for both the first metal film 825 and second metal film 835 may be selected from Ni, Ag, Au, Cu, Pt, Cr, Mo, Ti, Ta, Sn, W, Al, or a combination thereof. In the fourth embodiment, the same material may be used for the first metal film 825 and the second metal film 835 in order to decrease difficulty of the process of forming the metal layers and to increase process compatibility.

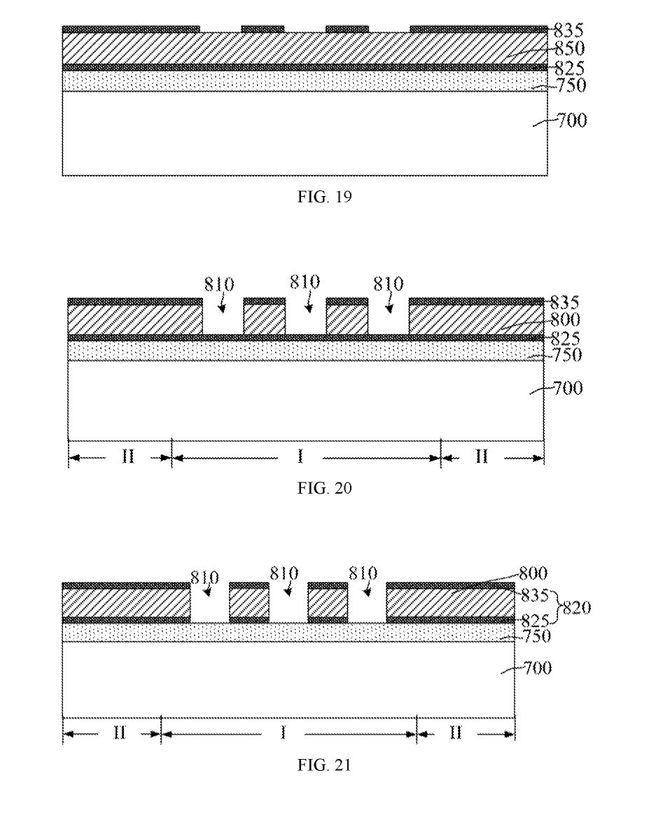

Referring to FIG. 19, the second metal film 835 is etched to expose a portion of the mask material layer 850.

The subsequent processes may include: patterning the second metal film 835, forming at least one through-hole in the second metal film 835, the remaining second metal film 835 exposing the mask material layer 850 at location of the through-hole after etching the second metal film 835.

Referring to FIG. 20, after etching the second metal film 835, the mask material layer 850 (referring to FIG. 19) is patterned to form a pattern region I and an adjacent shield region II, at least one through-hole 810 is formed in the pattern region I to pass through the mask material layer 850. The remaining mask material layer 850 becomes the mask pattern layer 800.

In the fourth embodiment, after etching the second metal film 835, the remaining second metal film 835 exposes a portion of the mask material layer at location of the through-hole 810. The remaining second metal film 835 covers the surface of the mask pattern layer facing away from the substrate 700.

Referring to FIG. 21, after formation of the mask pattern layer 800, a portion of the first metal film 825 is etched off from bottoms of the through-holes 810. The remaining first metal film 825 and the remaining second metal film 835 become the metal layer 820.

In the fourth embodiment, etching off a portion of the first metal film 825 from bottom of the through-hole 810 exposes the second sacrificial layer 750. This etching process allows for later formed first openings in the substrate 700 and the through-hole 810 to connect through from one to the other, thereby enabling the mask to function properly. Also, after etching off a portion of the first metal film 825 from bottom of the through-hole 810, the remaining first metal film 825 covers the surface of the mask pattern layer 800 that faces the substrate 700. Thus, the metal layer 820 may cover both surfaces of the mask pattern layer 800. Further processing is as for preceding embodiments, description of which is not repeated here.

In another specific embodiment, a mask fabrication process includes: providing a common semiconductor substrate, for example, a silicon substrate, where the substrate includes a first surface and a second surface opposite to the first surface; depositing a first sacrificial layer, for example, made of silicon dioxide material, on the first surface of the substrate; patterning the first sacrificial layer to form a pattern region and an adjacent shield region; depositing a mask material layer, for example, made of silicon nitride material, on the first sacrificial layer; patterning the mask material layer to form a mask pattern layer including a pattern region and an adjacent shield region in correspondence with the pattern of the first sacrificial layer; forming at least one through-hole passing through the mask material layer in the pattern region; depositing a second sacrificial layer, for example, made of silicon dioxide material, on the mask pattern layer to cover the surface and to fill in the through-hole of the mask pattern layer; patterning the second sacrificial layer to form a pattern region and an adjacent shield region in correspondence with the pattern of the first sacrificial layer; depositing a protection layer, for example, made of polycrystalline silicon or silicon nitride material, in the shield region of the second sacrificial layer; forming by a deep semiconductor etching process a plurality of openings in the second surface passing through the substrate, such that each of the openings corresponds to a pattern region; and removing in the pattern region a portion of the first and a portion of the second sacrificial layers using the substrate and the protection layer as masks.

Compared with conventional technology, the present disclosure provides advantages of the masks fabricated by using a semiconductor material for a substrate and using advanced semiconductor manufacturing processes, resulting in high quality of the mask and increased dimensional precision of the through-hole.

In the mask fabrication, a mask material layer is formed on the first surface of the substrate. The mask material layer is patterned and at least one through-hole is made in the pattern region before covering the mask pattern layer with a first sacrificial layer and a protection layer placed over the shield region of the first sacrificial layer. Then, the second surface of the substrate is etched to produce a plurality of openings through the substrate to expose the pattern region. Afterwards, using the protection layer and the substrate as masks, a portion of the first sacrificial layer in the pattern region is removed.

Among alternative embodiments: the mask pattern layer may include a third surface facing the first surface of the substrate, and a fourth surface opposite to the third surface; the mask may include a metal layer covering the fourth surface and sidewall of the through-hole, or the third surface, or the third surface and the fourth surface; the metal layer may function as a support to the mask pattern layer, decreasing the probability of mask pattern layer deformation or fracture. The mask is routinely cleaned after completion of the evaporation process. The metal layer may protect the mask pattern layer during the cleaning process, preventing corrosion of the mask layer by the cleaning solution, therefore increasing service life of the mask.

The embodiments disclosed herein are exemplary only. Other applications, alterations, modifications, or equivalents to the disclosed embodiments are obvious to those skilled in the art and are intended to be encompassed within the scope of the present disclosure. The protection of this disclosure is limited by the scope of the claims only.

What is claimed is:

1. A mask, comprising:
a substrate, including a first surface, a second surface opposite to the first surface, and a plurality of openings passing through the substrate;
a mask pattern layer, disposed on the first surface of the substrate and including a pattern region and a shield region adjacent to the pattern region, wherein the pattern region contains at least one through-hole passing through the mask pattern layer, and the pattern region is exposed by and corresponds to one opening of the plurality of openings;
a protection layer, disposed on the shield region of the mask pattern layer facing away from the substrate; and
a first sacrificial layer, disposed between the mask pattern layer and the protection layer.

2. The mask according to claim 1, wherein:
the mask pattern layer includes a third surface facing the first surface of the substrate, and a fourth surface opposite to the third surface, and
the mask further includes a metal layer, the metal layer covering the fourth surface and sidewalls of the at least one through-hole, or covering the third surface, or covering the third surface and the fourth surface.

3. The mask according to claim 1, further including:
a second sacrificial layer, disposed between the substrate and the mask pattern layer.

4. The mask according to claim 1, wherein:
the mask pattern layer is made of a material including silicon nitride, silicon oxide, silicon oxynitride, silicon carbon nitride, polycrystalline silicon, aluminum, or a combination thereof.

5. The mask according to claim 1, wherein:
the substrate is one or more selected from a silicon substrate, a germanium substrate, a silicon germanium substrate, a silicon carbide substrate, a gallium arsenide substrate, an indium gallium substrate, a silicon on insulator (SOI) substrate, and a germanium on insulator (GOI) substrate.

6. The mask according to claim 2, wherein:
the at least one through-hole has a cross section in a circular shape, and
when the metal layer covers the sidewalls of the at least one through-hole, the metal layer has a thickness less than a radius of the at least one through-hole.

7. The mask according to claim 1, wherein:
the through-hole has a depth ranging from about 2 μm to about 10 μm.

8. The mask according to claim 1, wherein:
the sacrificial layer has a thickness ranging from about 2 μm to about 10 μm.

9. The mask according to claim 1, wherein:
the protection layer has a thickness ranging from about 2 μm to about 10 μm.

10. A fabrication method of a mask, comprising:
providing a substrate, wherein the substrate includes a first surface and a second surface opposite to the first surface;
forming a mask material layer on the first surface of the substrate;
forming a mask pattern layer by: patterning the mask material layer to form a pattern region and a shield region adjacent to the pattern region, wherein the pattern region includes at least one through-hole passing through the mask material layer;
forming a first sacrificial layer covering the mask pattern layer and filling in the at least one through-hole;
forming a protection layer on the first sacrificial layer corresponding to the shield region of the mask pattern layer;
after forming the protection layer, etching the second surface of the substrate to form a plurality of openings passing through the substrate, with each opening exposing the pattern region of the mask pattern layer; and
after forming the plurality of openings, removing a portion of the first sacrificial layer corresponding to the pattern region of the mask pattern layer using the protection layer and the substrate as an etch mask.

11. The fabrication method according to claim 10, further including:
forming a metal layer by one of following processes including:
before forming the mask material layer on the first surface of the substrate, forming a metal film; and after forming the mask pattern layer and before forming the first sacrificial layer, forming the metal layer by etching the metal film under the at least one through-hole; and
before forming the mask material layer on the first surface of the substrate, forming a first metal film on the first surface; after forming the mask material layer on the first surface of the substrate and before forming the mask pattern layer, forming a second metal film on the mask material layer, etching the second metal film to expose a portion of the mask material layer corresponding to the at least one through-hole; and after forming the mask pattern layer and before forming the first sacrificial layer, etching the first metal film under the at least one through-hole, wherein the etched first metal film and the etched second metal film form the metal layer; and
after forming the mask pattern layer and before forming the first sacrificial layer, forming a metal film on the mask pattern layer, and a sidewall and a bottom of the at least one through-hole, and forming the metal layer by etching the metal film under the at least one through-hole.

12. The fabrication method according to claim 10, further including:
forming a second sacrificial layer on the first surface of the substrate before forming the mask material layer.

13. The fabrication method according to claim 12, further including:
removing a portion of the second sacrificial layer corresponding to the pattern region of the mask pattern layer using the protection layer and the substrate as an etch mask after forming the plurality of the openings.

14. The fabrication method according to claim 10, wherein:
the mask pattern layer is made of a material including silicon nitride, silicon oxide, silicon oxynitride, silicon carbon nitride, polycrystalline silicon, aluminum, or a combination thereof.

15. The fabrication method according to claim 12, wherein:
the second sacrificial layer is made of a material including silicon oxide, silicon nitride, amorphous carbon, germanium, or a combination thereof.

16. The fabrication method according to claim 11, wherein:
the metal layer is made of a material including Ni, Ag, Au, Cu, Pt, Cr, Mo, Ti, Ta, Sn, W, Al, or a combination thereof.

17. The fabrication method according to claim 10, wherein:
the protection layer is made of a material including silicon nitride, silicon oxide, silicon oxynitride, silicon carbon nitride, polycrystalline silicon, aluminum, or a combination thereof.

18. The fabrication method according to claim 10, wherein:
the first sacrificial layer is made of a material including silicon oxide, silicon nitride, amorphous carbon, germanium, or a combination thereof.

19. The fabrication method according to claim 10, wherein:
removing the portion of the first sacrificial layer includes one of a wet etching process and an ashing process.

20. The fabrication method according to claim 10, wherein:
the substrate is one or more selected from a silicon substrate, a germanium substrate, a silicon germanium substrate, a silicon carbide substrate, a gallium arsenide substrate, an indium gallium substrate, a silicon on insulator (SOI) substrate, and a germanium on insulator (GOI) substrate.
